(19) United States
(12) Patent Application Publication
(10) Pub. No.: US 2025/0126871 A1
(43) Pub. Date: Apr. 17, 2025

(54) SEMICONDUCTOR DEVICE AND METHOD OF FABRICATING THE SAME

(71) Applicant: Samsung Electronics Co., Ltd., Suwon-si (KR)

(72) Inventors: Jiwon PARK, Suwon-si (KR); Minseok JO, Suwon-si (KR); Jinyoung CHOI, Suwon-si (KR); Jun-Youp LEE, Suwon-si (KR); Hakjong LEE, Suwon-si (KR)

(73) Assignee: Samsung Electronics Co., Ltd., Suwon-si (KR)

(21) Appl. No.: 18/630,286

(22) Filed: Apr. 9, 2024

(30) Foreign Application Priority Data
Oct. 13, 2023 (KR) 10-2023-0137071

(51) Int. Cl. H01L 29/423; H01L 21/762; H01L 23/522; H01L 23/528; H01L 27/092; H01L 29/06; H01L 29/08; H01L 29/66; H01L 29/786

(52) U.S. Cl. CPC H10D 64/513; H01L 21/76224; H01L 23/5226; H01L 23/528; H01L 23/5286; H10D 62/151; H10D 64/017; H10D 84/85; H10D 30/6735; H10D 30/6757; H10D 62/121

(57) ABSTRACT

A semiconductor device may include an active pattern on a substrate, defined by a trench, and extending in a first direction, a device isolation layer filling the trench, the substrate including a first surface in contact with a bottom surface of the device isolation layer and a second surface opposite to the first surface, a gate electrode extending in a second direction and cross the active pattern, the second direction crossing the first direction, a first division structure spaced apart from the gate electrode in the first and extending in the second direction, and a power delivery network layer on the second surface of the substrate. The first division structure may penetrate the device isolation layer, and a bottom surface of the first division structure may be coplanar with the second surface of the substrate.

### CROSS-REFERENCE TO RELATED APPLICATIONS

This U.S. non-provisional patent application claims priority under 35 U.S.C. § 119 to Korean Patent Application No. 10-2023-0137071, filed on Oct. 13, 2023, in the Korean Intellectual Property Office, the entire contents of which are hereby incorporated by reference.

### BACKGROUND

The present disclosure relates to semiconductor devices and/or methods of fabricating the same, and in particular, to semiconductor devices including a field effect transistor and/or methods of fabricating the same.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. Various studies are being conducted to overcome technical limitations associated with the scale-down of the semiconductor device and to realize high-performance semiconductor devices.

### SUMMARY

An example embodiment of the inventive concepts provide semiconductor devices with improved electrical and reliability characteristics.

An example embodiment of the inventive concepts provide methods of fabricating a semiconductor device with improved electrical and reliability characteristics.

According to an example embodiment of the inventive concepts, a semiconductor device may include an active pattern on a substrate, defined by a trench, and extended in a first direction, a device isolation layer filling the trench, the substrate including a first surface in contact with a bottom surface of the device isolation layer and a second surface opposite to the first surface, a gate electrode extending in a second direction and cross the active pattern, the second direction crossing the first direction, a first division structure spaced apart from the gate electrode in the first direction and extending in the second direction, and a power delivery network layer on the second surface of the substrate. The first division structure may penetrate the device isolation layer, and a bottom surface of the first division structure may be coplanar with the second surface of the substrate.

According to an example embodiment of the inventive concepts, a semiconductor device may include an active pattern on a substrate, defined by a trench, and extending in a first direction, a device isolation layer filling the trench, a source/drain pattern on the active pattern, a gate electrode extending in the first direction to cross the active pattern, a first division structure extended from the gate electrode in the first direction, a power delivery network layer on a bottom surface of the substrate, a first metal layer on the source/drain pattern, the first metal layer including a power line, and a penetration via vertically penetrating the substrate and the device isolation layer and connecting the power line to the power delivery network layer. The penetration via may be at a side of the division structure and may be spaced apart from the division structure, and a bottom surface of the division structure may be coplanar with a bottom surface of the penetration via.

According to an example embodiment of the inventive concepts, a semiconductor device may include an active pattern on a substrate and extended in a first direction, a device isolation layer defining the active pattern, a channel pattern and a source/drain pattern on the active pattern, the channel pattern including a plurality of semiconductor patterns stacked to be spaced apart from each other, a gate electrode on the channel pattern and extending in a second direction crossing the first direction, the gate electrode including an inner electrode interposed between adjacent ones of the semiconductor patterns, a gate insulating layer interposed between the gate electrode and the channel pattern, an inner spacer between the inner electrode and the source/drain pattern, a gate spacer on a side surface of the gate electrode, a gate capping pattern on a top surface of the gate electrode, a gate cutting pattern penetrating the gate electrode, an interlayer insulating layer on the gate capping pattern and the gate cutting pattern, an active contact penetrating the interlayer insulating layer and electrically connected to the source/drain pattern, a gate contact penetrating the interlayer insulating layer and the gate capping pattern and electrically connected to the gate electrode, a first metal layer on the interlayer insulating layer, the first metal layer including a first upper interconnection line electrically connected to the active contact, a second metal layer on the first metal layer, the second metal layer including a second upper interconnection line electrically connected to the first metal layer, a power delivery network layer on a bottom surface of the substrate, the power delivery network layer including a lower interconnection line, a penetration via penetrating the device isolation layer and the substrate and vertically connecting the first upper interconnection line of the first metal layer to the lower interconnection line, and a first division structure spaced apart from the gate electrode in the first direction and extending in the second direction. The first division structure may penetrate the device isolation layer and the substrate. The bottom surface of the substrate may be located at a first level, and the first division structure may have the smallest width at the first level, when measured in the first direction.

### BRIEF DESCRIPTION OF THE DRAWINGS

FIGS. 1 to 3 are conceptual diagrams illustrating logic cells in a semiconductor device according to an example embodiment of the inventive concepts.

FIG. 4 is a plan view illustrating a semiconductor device according to an example embodiment of the inventive concepts.

FIGS. 5A to 5D are sectional views taken along lines A-A′, B-B′, C-C′, and D-D′ of FIG. 4, respectively.

FIGS. 6A, 6B, 6C, 7A, 7B, 7C, 8A, 8B, 8C, 9A, 9B, 9C, 10A, 10B, 10C, 10D, 11A, 11B, 12, 13, 14, 15A, 15B, 16, 17, 18, and 19 are sectional views illustrating a method of fabricating a semiconductor device, according to an example embodiment of the inventive concepts.

### DETAILED DESCRIPTION

While the term “same” is used in description of example embodiments, it should be understood that some imprecisions may exist. Thus, when one element is referred to as being the same as another element, it should be understood that the one element is the same as another element within a desired manufacturing tolerance range (e.g., ±10%).

When the terms “about” or “substantially” are used in this specification in connection with a numerical value, it is intended that the associated numerical value includes a manufacturing tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

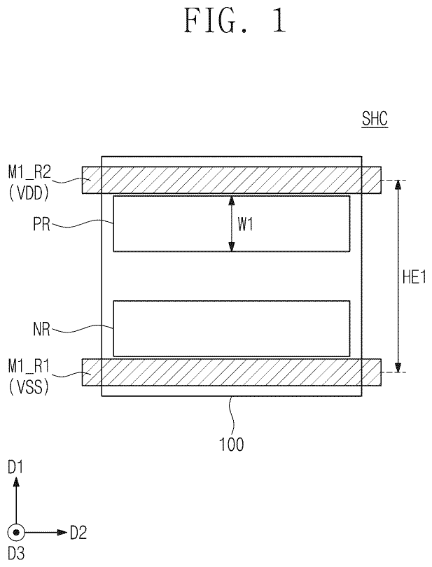

FIGS. 1 to 3 are conceptual diagrams illustrating logic cells in a semiconductor device according to an example embodiment of the inventive concepts.

Referring to FIG. 1, a single height cell SHC may be provided. For example, a first power line M1_R1 and a second power line M1_R2 may be provided below a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. The single height cell SHC may include one PMOSFET region PR and one NMOSFET region NR. In other words, the single height cell SHC may have a CMOS structure provided between the first and second power lines M1_R1 and M1_R2.

Each of the PMOSFET and NMOSFET regions PR and NR may have a width W1 in a first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. In the present specification, the logic cell may mean a logic device (e.g., AND, OR, XOR, XNOR, inverter, and so forth) that is configured to execute a specific function. In other words, the logic cell may include transistors constituting the logic device and interconnection lines connecting the transistors to each other.

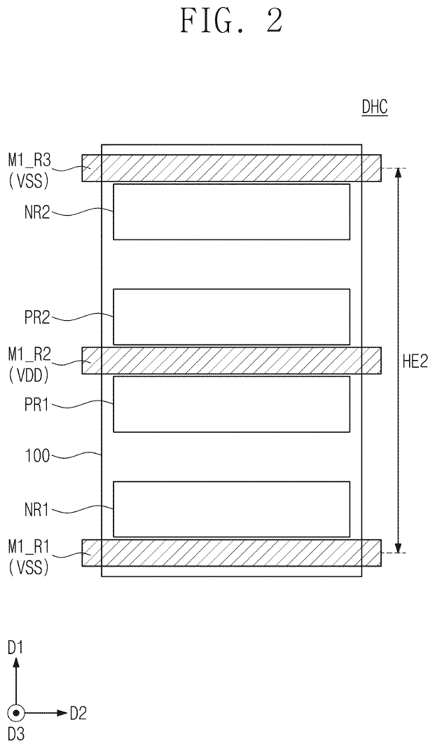

Referring to FIG. 2, a double height cell DHC may be provided. In detail, a first power line M1_R1, a second power line M1_R2, and a third power line M1_R3 may be provided on the substrate 100. The second power line M1_R2 may be disposed between the first power line M1_R1 and the third power line M1_R3. The third power line M1_R3 may be a conduction path, to which the source voltage VSS is provided.

The double height cell DHC may be defined between the first power line M1_R1 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the first power line M1_R1. The second NMOSFET region NR2 may be adjacent to the third power line M1_R3. The first and second PMOSFET regions PR1 and PR2 may be adjacent to the second power line M1_R2. When viewed in a plan view, the second power line M1_R2 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times the channel size of the PMOS transistor of the single height cell SHC. In this case, the double height cell DHC may be operated at a higher speed than the single height cell SHC. In an example embodiment, the double height cell DHC shown in FIG. 2 may be defined as a multi-height cell. Although not shown, the multi-height cell may include a triple height cell whose cell height is about three times that of the single height cell SHC.

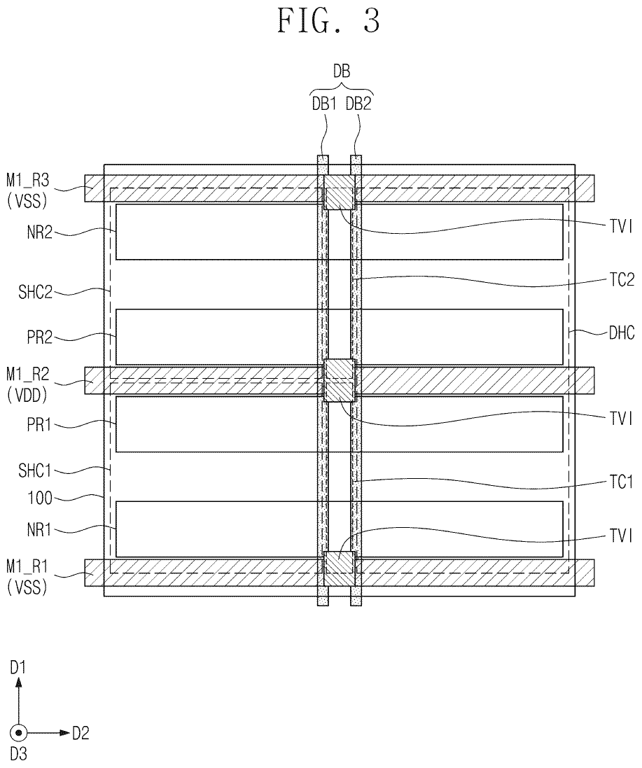

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the second and third power lines M1_R2 and M1_R3. The second single height cell SHC2 may be adjacent to the first single height cell SHC1 in the first direction D1.

The double height cell DHC may be disposed between the first and third power lines M1_R1 and M1_R3. The double height cell DHC may be adjacent to the first and second single height cells SHC1 and SHC2 in a second direction D2.

A first tab cell TC1 may be provided between the first single height cell SHC1 and the double height cell DHC. A second tab cell TC2 may be provided between the second single height cell SHC2 and the double height cell DHC. The first tab cell TC1 and the second tab cell TC2 may be aligned to each other in the first direction D1.

Each of the first and second tab cells TC1 and TC2 may be a cell, which is configured to apply a voltage from a power delivery network, which will be described below, to at least one of the power lines M1_R1 to M1_R3. The tab cell may not include the logic device, unlike the logic cell. That is, the tap cell may be configured to apply a voltage to the power line but may be just a dummy cell that does not serve as a circuit element.

As illustrated in FIG. 3, the first and second tab cells TC1 and TC2 may be disposed in a cell region with the logic cells SHC1, SHC2, and DHC to be placed between the logic cells SHC1, SHC2, and DHC. FIG. 3 illustrates an example of how the first and second tab cells TC1 and TC2 and the logic cells SHC1, SHC2, and DHC can be arranged, but there may be many other possible arrangements for the logic and tab cells.

In an example embodiment, a first division structure DB1 may be provided between the first tab cell TC1 and the first single height cell SHC1 and between the second tab cell TC2 and the second single height cell SHC2. A second division structure DB2 may be provided between the first tab cell TC1 and the double height cell DHC and between the second tab cell TC2 and the double height cell DHC. An active region of the logic cell SHC1, SHC2, or DHC may be electrically disconnected from an active region of the tab cell TC1 or TC2 by a division structure DB.

The first and second tab cells TC1 and TC2 may include penetration vias TVI, which are connected to the first to third power lines M1_R1, M1_R2, and M1_R3, respectively. The first to third power lines M1_R1, M1_R2, and M1_R3 may be electrically connected to a power delivery network, which is disposed below the substrate 100, through the penetration vias TVI.

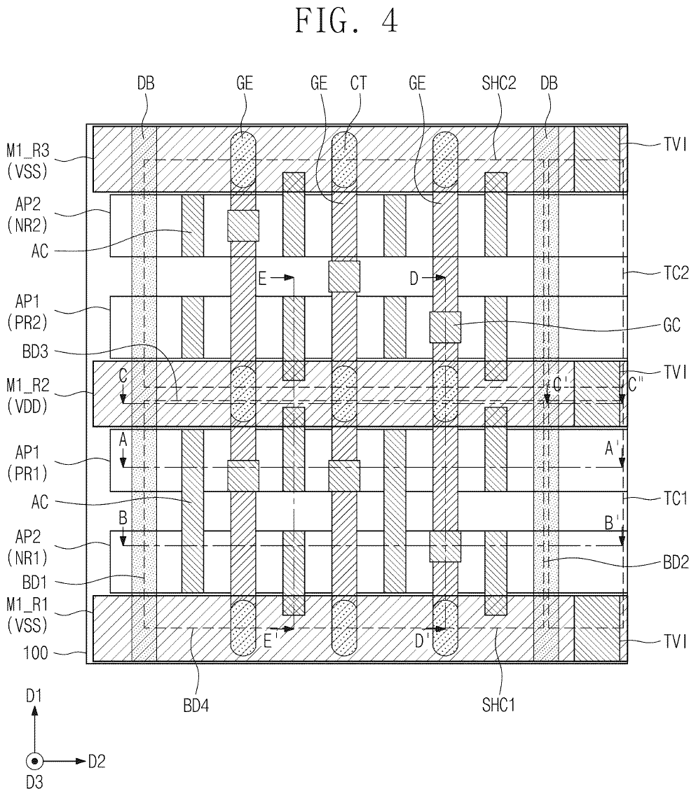

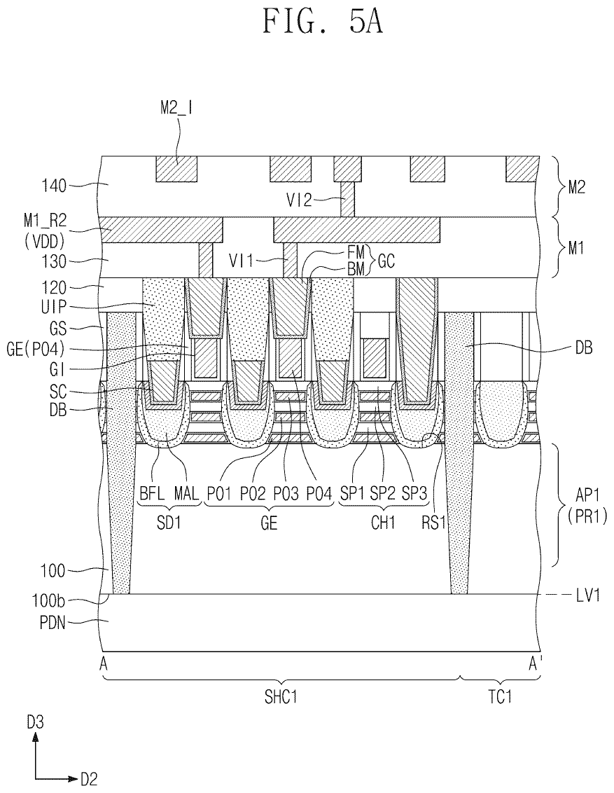

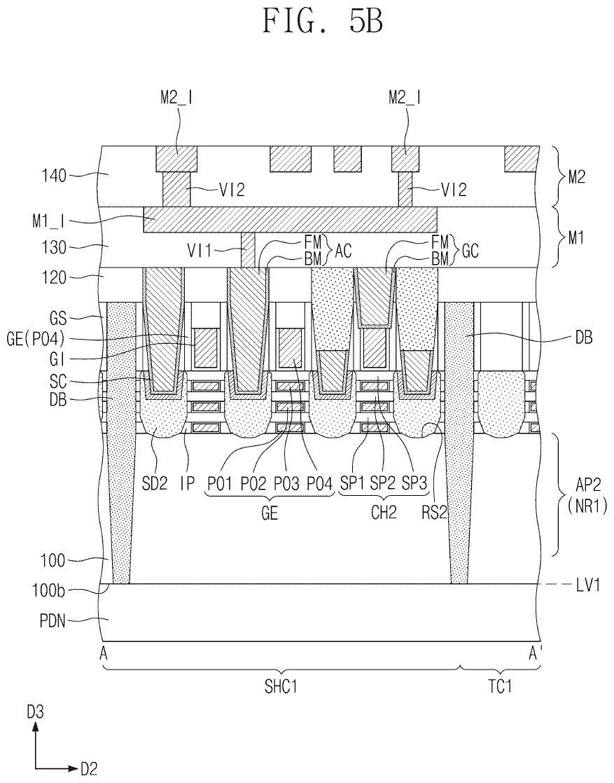

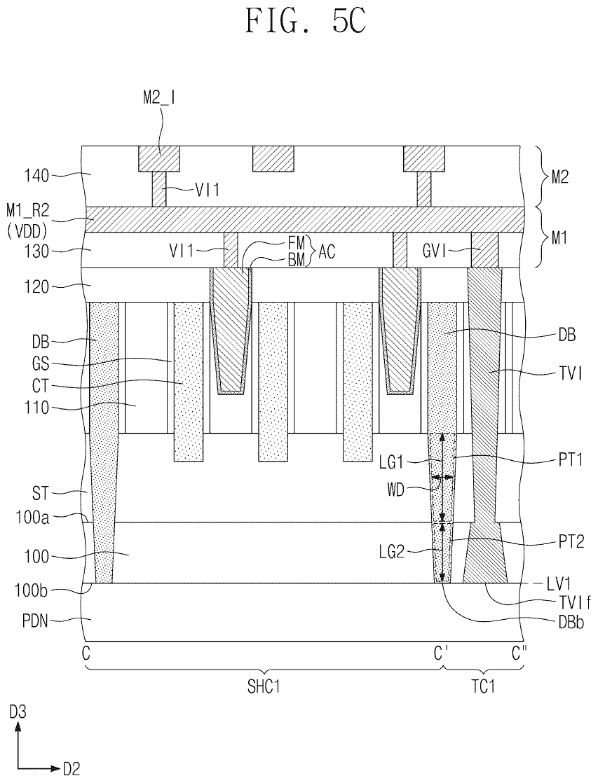

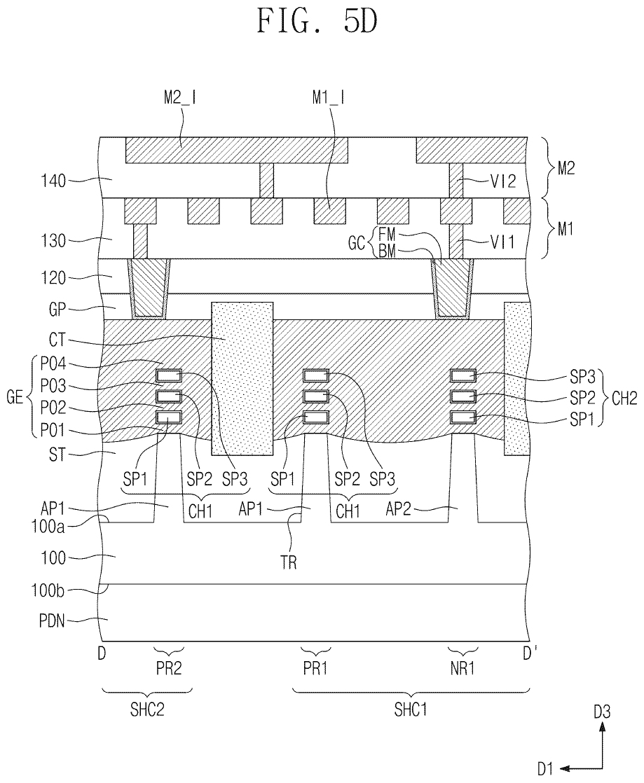

FIG. 4 is a plan view illustrating a semiconductor device according to an example embodiment of the inventive concepts. FIGS. 5A to 5D are sectional views taken along lines A-A′, B-B′, C-C′, and D-D′ of FIG. 4, respectively. FIGS. 4 and 5A to 5D illustrate a detailed example of the semiconductor device shown in FIG. 3, including the first and second single height cells SHC1 and SHC2 and the first and second tab cells TC1 and TC2.

Referring to FIG. 4 and FIGS. 5A to 5D, the first and second single height cells SHC1 and SHC2 and the first and second tab cells TC1 and TC2 may be provided on the substrate 100. Logic transistors constituting a logic circuit may be disposed on each of the first and second single height cells SHC1 and SHC2. Dummy transistors may be disposed on each of the first and second tab cells TC1 and TC2. The substrate 100 may be a semiconductor substrate that is formed of or includes silicon, germanium, silicon germanium, a compound semiconductor material, or the like. In an example embodiment, the substrate 100 may be a silicon wafer. The substrate 100 may include a top surface 100a and a bottom surface 100b, which are opposite to each other.

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may be extended in the second direction D2. Each of the first and second active patterns AP1 and AP2 may be a vertically protruding portion of the substrate 100.

A device isolation layer ST may be provided on the substrate 100 to define the first and second active patterns AP1 and AP2. The device isolation layer ST may fill the trench TR. The device isolation layer ST may include a silicon oxide layer. The device isolation layer ST may not cover first and second channel patterns CH1 and CH2, which will be described below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon. In an example embodiment, each of the first to third semiconductor patterns SP1, SP2, and SP3 may be a nanosheet.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between a pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. As an example, a top surface of each of the first and second source/drain patterns SD1 and SD2 may be positioned at substantially the same level as a top surface of the third semiconductor pattern SP3. However, in an example embodiment, the top surface of each of the first and second source/drain patterns SD1 and SD2 may be higher than the top surface of the third semiconductor pattern SP3.

The first source/drain patterns SD1 may include a semiconductor material (e.g., SiGe) whose lattice constant is greater than that of the substrate 100. In this case, the pair of the first source/drain patterns SD1 may exert a compressive stress on the first channel patterns CH1 therebetween. The second source/drain patterns SD2 may be formed of or include the same semiconductor element (e.g., Si) as the substrate 100.

Each of the first source/drain patterns SD1 may include a buffer layer BFL and a main layer MAL on the buffer layer BFL. Referring back to FIG. 5A, the buffer layer BFL may cover an inner surface of the first recess RS1. The buffer layer BFL may have a ‘U’-shaped section corresponding to a profile of the first recess RS1.

The main layer MAL may fill an unfilled region of the first recess RS1 covered with the buffer layer BFL. The main layer MAL may have a volume that is greater than that of the buffer layer BFL. Each of the buffer and main layers BFL and MAL may be formed of or include silicon germanium (SiGe). For example, the buffer layer BFL may contain a relatively low concentration of germanium (Ge). In another example embodiment, the buffer layer BFL may contain only silicon (Si), without germanium (Ge). A germanium concentration of the buffer layer BFL may range from 0 at % to 30 at %.

The main layer MAL may contain a relatively high concentration of germanium. In an example embodiment, the germanium concentration of the main layer MAL may range from 30 at % to 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may contain an impurity (e.g., boron, gallium, or indium) that allows the first source/drain pattern SD1 to have a p-type conductivity. The impurity concentration of the main layer MAL may be higher than the impurity concentration of the buffer layer BFL.

Each of the second source/drain patterns SD2 may be formed of or include silicon (Si). The second source/drain pattern SD2 may further contain impurities (e.g., phosphorus, arsenic, or antimony) that allow the second source/drain pattern SD2 to have an n-type conductivity.

The gate electrodes GE may be provided to cross the first and second channel patterns CH1 and CH2 and to extend in the first direction D1. The gate electrodes GE may be arranged at a first pitch in the second direction D2. Each of the gate electrodes GE may vertically overlap the first and second channel patterns CH1 and CH2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5D, the gate electrode GE may be provided on a top surface TS, a bottom surface BS, and opposite side surfaces SW of each of the first to third semiconductor patterns SP1, SP2, and SP3. That is, the transistor according to the present example embodiment may be a three-dimensional field effect transistor (e.g., multibridge-channel metal-oxide-semiconductor field-effect transistor (MBCFET) or gate-all-around field-effect transistor (GAAFET)) in which the gate electrode GE is provided to three-dimensionally surround the channel pattern.

Gate cutting patterns CT may be provided on a boundary region between the first and second single height cells SHC1 and SHC2. The gate cutting patterns CT may be arranged at the first pitch along the boundary. When viewed in a plan view, the gate cutting patterns CT may be disposed to be overlapped with the gate electrodes GE, respectively. The gate cutting patterns CT may be formed of or include at least one of insulating materials (e.g., silicon oxide, silicon nitride, or combinations thereof).

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 aligned to each other in the first direction D1. That is, the gate electrode GE extending in the first direction D1 may be divided into a plurality of the gate electrodes GE by the gate cutting patterns CT.

Referring back to FIG. 4 and FIGS. 5A to 5D, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. The gate spacers GS may be formed of or include at least one of SiCN, SiCON, or SiN. In an example embodiment, the gate spacers GS may be a multi-layered structure, which includes at least two different materials selected from SiCN, SiCON, and SiN.

A gate capping pattern GP may be provided on the gate electrode GE. The gate capping pattern GP may be extended along the gate electrode GE or in the first direction D1. The gate capping pattern GP may be formed of or include a material having an etch selectivity with respect to first and second interlayer insulating layers 110 and 120, which will be described below. For example, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and opposite side surfaces SW of each of the first to third semiconductor patterns SP1, SP2, and SP3. The gate insulating layer GI may cover the top surface of the device isolation layer ST below the gate electrode GE.

In an example embodiment, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first electrode pattern and a second electrode pattern on the first electrode pattern. The first electrode pattern may be provided on the gate insulating layer GI and may be adjacent to the first to third semiconductor patterns SP1, SP2, and SP3. The first electrode pattern may include a work-function metal, which can be used to adjust a threshold voltage of the transistor. By adjusting a thickness and composition of the first electrode pattern, it may be possible to realize a transistor having a desired threshold voltage. For example, the first to third inner electrodes PO1, PO2, and PO3 of the gate electrode GE may be composed of the first electrode pattern including the work-function metal. The first electrode pattern may include a metal nitride layer. For example, the first electrode pattern may include a layer that is composed of at least one metallic material, which is selected from the group consisting of titanium (Ti), tantalum (Ta), aluminum (Al), tungsten (W) and molybdenum (Mo), and nitrogen (N). In an example embodiment, the first electrode pattern may further include carbon (C). The first electrode pattern may include a plurality of work function metal layers which are stacked.

The second electrode pattern may be formed of or include a metallic material whose resistance is lower than the first electrode pattern. For example, the second electrode pattern may be formed of or include at least one metallic material, which is selected from the group consisting of tungsten (W), aluminum (Al), titanium (Ti), and tantalum (Ta). In an example embodiment, the outer electrode PO4 of the gate electrode GE may include the first electrode pattern and the second electrode pattern on the first electrode pattern.

Referring back to FIG. 5B, inner spacers IP may be provided on the first and second NMOSFET regions NR1 and NR2. That is, the inner spacers IP may be provided on the second active pattern AP2. The inner spacers IP may be interposed between the second source/drain pattern SD2 and the first to third inner electrodes PO1, PO2, and PO3 of the gate electrode GE, respectively. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

A first interlayer insulating layer 110 may be provided on the substrate 100. The first interlayer insulating layer 110 may cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. In an example embodiment, at least one of the first to fourth interlayer insulating layers 110 to 140 may include a silicon oxide layer.

A pair of division structures DB, which are opposite to each other in the second direction D2, may be provided at both sides of each of the first and second single height cells SHC1 and SHC2. For example, a pair of the division structures DB may be provided on the first and second borders BD1 and BD2 of the first single height cell SHC1, respectively. The division structure DB may be extended in the first direction D1 to be parallel to the gate electrodes GE. The division structure DB may be spaced apart from the gate electrodes GE in the second direction D2. A pitch between the division structure DB and the gate electrode GE adjacent thereto may be equal to the first pitch.

Active contacts AC may be provided to penetrate the first and second interlayer insulating layers 110 and 120 and to be electrically connected to the first and second source/drain patterns SD1 and SD2, respectively. A pair of the active contacts AC may be provided at both sides of the gate electrode GE, respectively. When viewed in a plan view, the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. Although not shown, the active contact AC may be provided to cover a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate the second interlayer insulating layer 120 and the gate capping pattern GP and may be electrically connected to the gate electrodes GE, respectively. When viewed in a plan view, two gate contacts GC on the first single height cell SHC1 may be disposed to overlap the first PMOSFET region PR1. That is, the two gate contacts GC on the first single height cell SHC1 may be provided on the first active pattern AP1 (e.g., see FIG. 5A). When viewed in a plan view, one gate contact GC on the first single height cell SHC1 may be disposed to overlap the first NMOSFET region NR1. In other words, the one gate contact GC on the first single height cell SHC1 may be provided on the second active pattern AP2 (e.g., see FIG. 5B).

The gate contact GC may be freely disposed on the gate electrode GE, without any restrictions on its position. For example, the gate contacts GC on the second single height cell SHC2 may be disposed on the second PMOSFET region PR2, on the second NMOSFET region NR2, and on the device isolation layer ST filling the trench TR, respectively (e.g., see FIG. 4).

In an example embodiment, referring to FIGS. 5A and 5B, an upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, it may be possible to mitigate or prevent the gate contact GC and the active contact AC that are adjacent to each other from being in contact with each other, thereby mitigating or preventing a short circuit issue from occurring therebetween. The upper insulating pattern UIP may be formed of or include at least one of silicon-based insulating materials (e.g., silicon oxide, silicon nitride, and silicon oxynitride).

Each of the active and gate contacts AC and GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may be provided to cover side and bottom surfaces of the conductive pattern FM. In an example embodiment, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

The first to third power lines M1_R1, M1_R2, and M1_R3 may be extended in the second direction D2 to be parallel to each other. The first power line M1_R1 may be placed on a border of the first single height cell SHC1. The second power line M1_R2 may be placed on a boundary between the first and second single height cells SHC1 and SHC2. The third power line M1_R3 may be placed on a border of the second single height cell SHC2.

Referring back to FIGS. 5C and 5D, the second power line M1_R2 may be electrically connected to at least one active contact AC. A first via VI1 may be provided between the second power line M1_R2 and the active contact AC.

Referring back to FIGS. 4 and 5C, the penetration vias TVI may be provided in the first and second tap cells TC1 and TC2. The penetration vias TVI may be electrically connected to the first to third power lines M1_R1, M1_R2, and M1_R3, respectively. The penetration vias TVI may electrically connect the first to third power lines M1_R1, M1_R2, and M1_R3 to a power delivery network layer PDN to be described below. Top surfaces of the penetration vias TVI may be coplanar with a top surface of the second interlayer insulating layer 120. Bottom surfaces of the penetration vias TVI may be coplanar with or lower than the bottom surface 100b of the substrate 100. The penetration vias TVI may be formed of or include at least one of tungsten (W), cobalt (Co), or molybdenum (Mo).

The division structure DB will be described in more detail with reference to FIG. 5C. The division structure DB may be provided to vertically penetrate the gate capping pattern GP and the gate electrode GE. The division structure DB may be provided to penetrate the device isolation layer ST and the substrate 100. A bottom surface DBb of the division structure DB may be coplanar with the bottom surface 100b of the substrate 100. The bottom surface DBb of the division structure DB and the bottom surface 100b of the substrate 100 may be located at a first level LV1. For example, the lowermost portion of the division structure DB may be located at the first level LV1. The bottom surface DBb of the division structure DB may be in direct contact with a lower interconnection line in the power delivery network layer PDN.

The bottom surface DBb of the division structure DB may be coplanar with a bottom surface TVIf of the penetration via TVI. For example, the bottom surface TVIf of the penetration via TVI may be located at the first level LV1. As another example, the bottom surface TVIf of the penetration via TVI may be located at a level lower than the bottom surface 100b of the substrate 100 and the bottom surface DBb of the division structure DB.

The division structure DB may include a first portion PT1 and a second portion PT2, which are respectively provided in the device isolation layer ST and the substrate 100. A mean width of the first portion PT1 in the second direction D2 may be larger than a mean width of the second portion PT2 in the second direction D2. A vertical length LG1 of the first portion PT1 may be larger than a vertical length LG2 of the second portion PT2, but the inventive concepts are not limited to this example.

The division structure DB may have a first width WD in the second direction D2. The first width WD may decrease as a distance to the bottom surface DBb of the division structure DB decreases. As an example, the smaller the distance to the first level LV1, the smaller the first width WD may be. The division structure DB may have the smallest width in the second direction D2 at the first level LV1.

The division structure DB may include a material having an etch selectivity with respect to the substrate 100. For example, the division structure DB may be formed of or include an insulating material (e.g., silicon oxide, silicon nitride, silicon oxynitride, or combinations thereof). Although not shown, a portion of the bottom surface 100b of the substrate 100 may be convex in the third direction D3 and may have a specific curvature. For example, the portion of the bottom surface 100b of the substrate 100 may be recessed into the substrate 100. This is because the bottom surface 100b of the substrate 100 is etched by a planarization process to be described below.

The division structure DB may electrically separate an active region of one cell from an active region of a neighboring cell. As an example, the double height cell DHC adjacent to the first single height cell SHC1 may include a second division structure DB2 (e.g., see FIG. 3). A bottom surface of the second division structure DB2 may be coplanar with a bottom surface of a device isolation layer in the double height cell DHC. A vertical length of the second division structure DB2 may be smaller than a vertical length of the division structure DB of the first single height cell SHC1. For example, the division structures DB in adjacent cells may have different vertical lengths from each other.

A power delivery network layer PDN may be provided under the substrate 100. The power delivery network layer PDN may be electrically connected to the first to third power lines M1_R1, M1_R2, and M1_R3 by the penetration vias TVI.

In an example embodiment, the power delivery network layer PDN may include an interconnection network, which is used to apply the source voltage VSS to the first and third power lines M1_R1 and M1_R3. The power delivery network layer PDN may include an interconnection network, which is used to apply the drain voltage VDD to the second power line M1_R2.

Referring back to FIG. 4 and FIGS. 5A to 5D, the first metal layer M1 may further include first interconnection lines M1_I. The first interconnection lines M1_I may be extended in the second direction D2 to be parallel to each other.

The first metal layer M1 may further include the first vias VI1. The first vias VI1 may be provided below the first interconnection lines M1_I of the first metal layer M1, respectively. The active contact AC and the first interconnection line M1_I may be electrically connected to each other through the first via VI1. The gate contact GC and the first interconnection line M1_I may be electrically connected to each other through the first via VI1.

The first interconnection line M1_I of the first metal layer M1 and the first via VI1 thereunder may be separately formed by different processes. That is, each of the first interconnection line M1_I and the first via VI1 of the first metal layer M1 may be formed by a single damascene process. The semiconductor device according to the present example embodiment may be fabricated using a sub-20 nm process.

A second metal layer M2 may be provided in a fourth interlayer insulating layer 140. The second metal layer M2 may include a plurality of second interconnection lines M2_I. Each of the second interconnection lines M2_I of the second metal layer M2 may be a line- or bar-shaped pattern extending in the first direction D1. In other words, the second interconnection lines M2_I may be extended in the first direction D1 to be parallel to each other. The second metal layer M2 may further include second vias VI2, which are provided below the second interconnection lines M2_I, respectively. The first interconnection line M1_I of the first metal layer M10 and the second interconnection line M2_I of the second metal layer M2 may be electrically connected to each other through the second via VI2. As an example, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or include the same conductive material or different conductive materials. In an example embodiment, the first interconnection line M1_I of the first metal layer M1 and the second interconnection line M2_I of the second metal layer M2 may be formed of or include at least one of metallic materials (e.g., aluminum, copper, tungsten, molybdenum, ruthenium, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

According to an example embodiment of the inventive concepts, the division structure DB may penetrate the device isolation layer ST and the substrate 100 and may have a bottom surface that is coplanar with the bottom surface 100b of the substrate 100. Here, the division structure DB may include a material having an etch selectivity with respect to the substrate 100, and in this case, it may be possible to adjust a thickness of the substrate 100 in a planarization process to be described below. Furthermore, the division structures DB may have at least two different heights depending on the types of the devices, and this may allow for a difference in the thickness of the substrate 100, depending on the types of the devices. By using the division structure DB, it may be possible to electrically separate adjacent ones of the cells from each other and to adjust the height of the bottom surface 100b of the substrate 100. Thus, the electric characteristics and reliability of the semiconductor device may be improved.

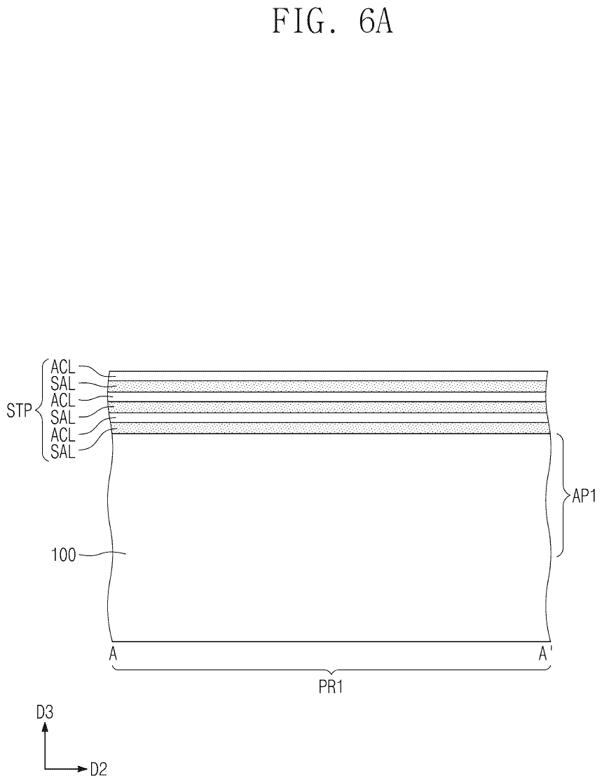

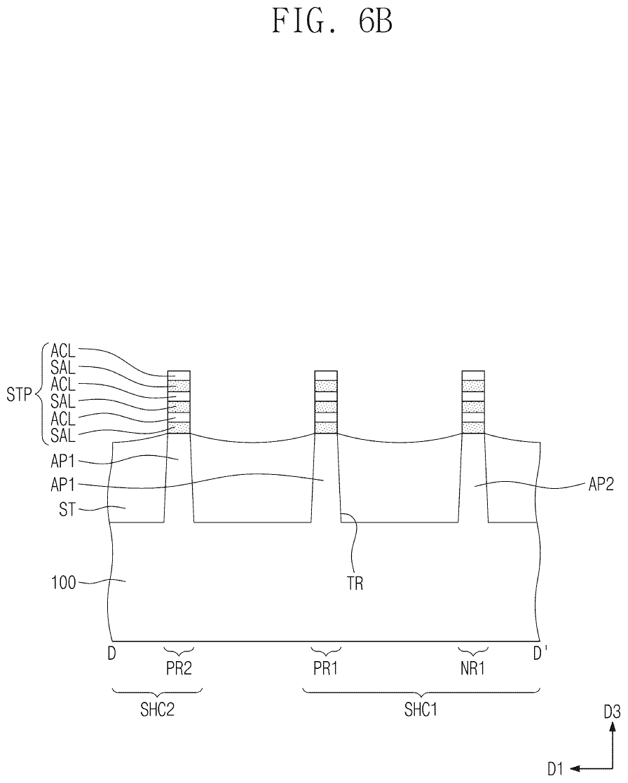

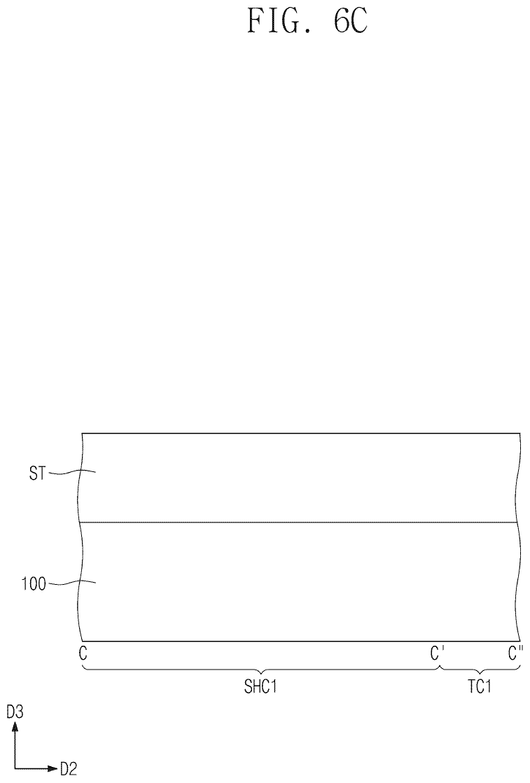

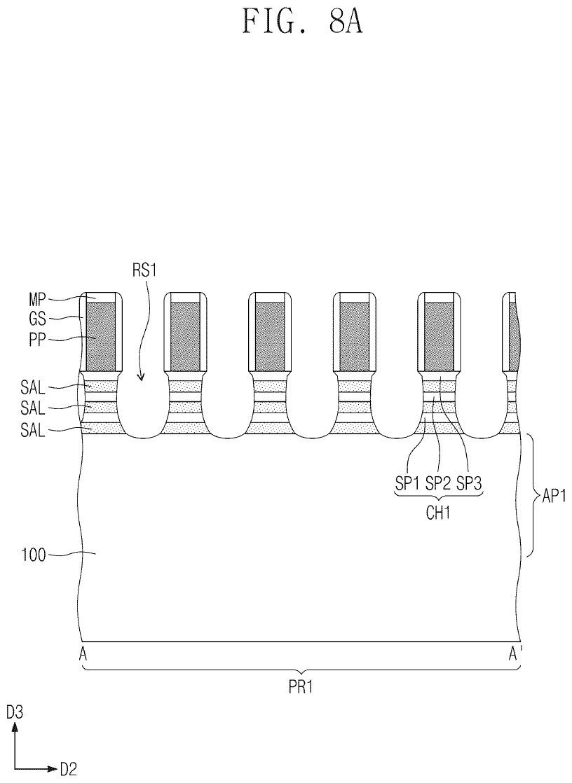

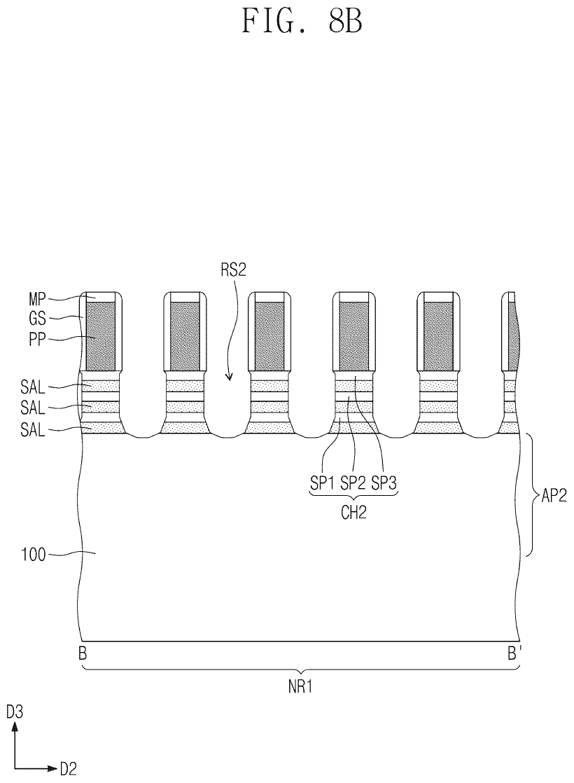

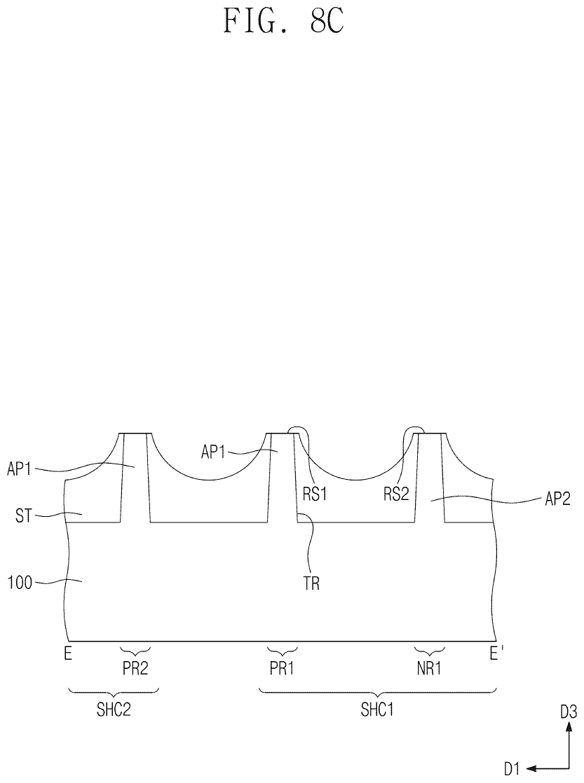

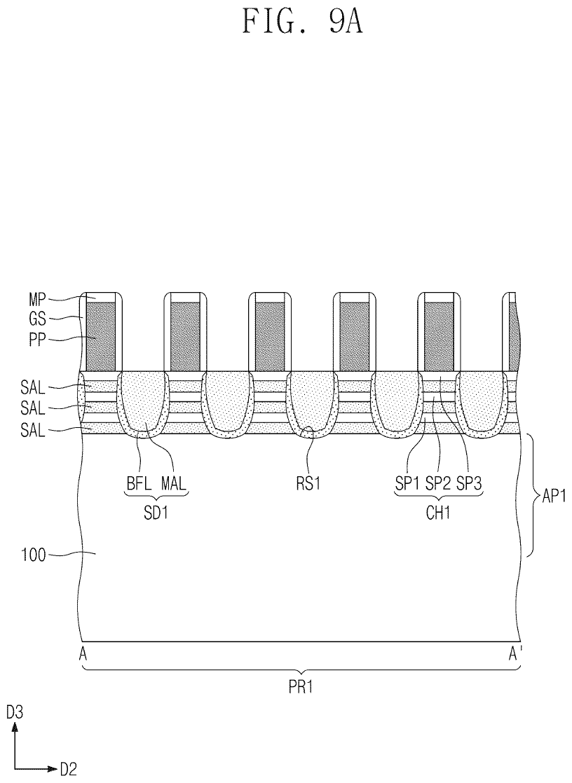

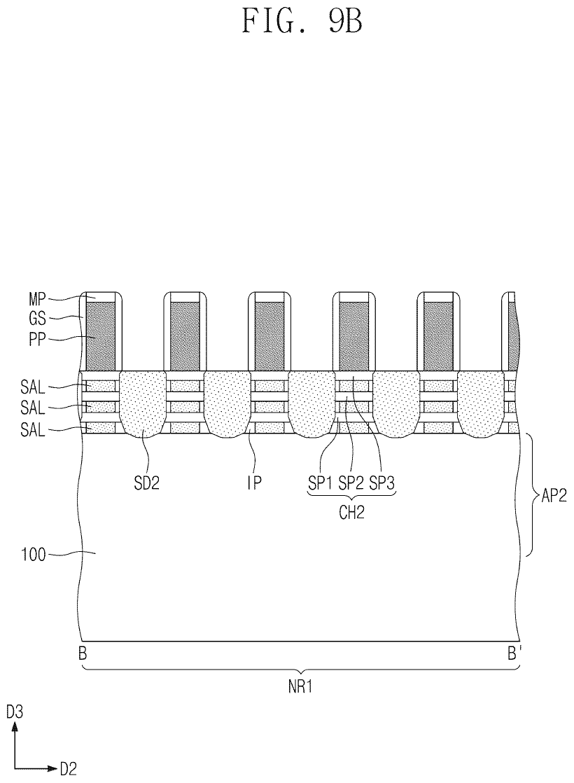

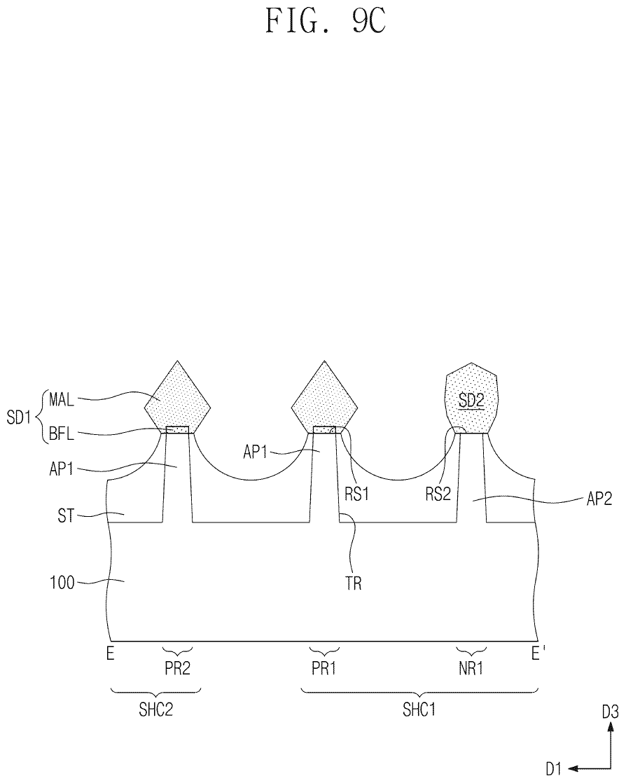

FIGS. 6A to 19 are sectional views illustrating a method of fabricating a semiconductor device, according to an example embodiment of the inventive concepts. FIGS. 6A, 7A, 8A, 9A, 10A, 11A, and 15A are sectional views corresponding to the line A-A′ of FIG. 4. FIGS. 8B, 9B, 10B, 11B, and 15B are sectional views corresponding to the line B-B′ of FIG. 4. FIGS. 6C, 7B, 10C, 12, 13, 14, 16, 17, 18, and 19 are sectional views corresponding to the line C-C′ of FIG. 4. FIGS. 6B, 7C, and 10D are sectional views corresponding to the line D-D′ of FIG. 4. FIGS. 8C and 9C are sectional views corresponding to the line E-E′ of FIG. 4.

Referring to FIGS. 6A, 6B, and 6C, the substrate 100 including the first and second PMOSFET regions PR1 and PR2 and the first and second NMOSFET regions NR1 and NR2 may be provided. First and second semiconductor layers ACL and SAL, which are alternately stacked on the substrate 100, may be formed. Each of the first and second semiconductor layers ACL and SAL may be formed of or include at least one of silicon (Si), germanium (Ge), or silicon-germanium (SiGe), but the first and second semiconductor layers ACL and SAL may be formed of different materials from each other.

The second semiconductor layer SAL may be formed of or include a material that is chosen to have an etch selectivity with respect to the first semiconductor layer ACL. For example, the first semiconductor layers ACL may be formed of or include silicon (Si), and the second semiconductor layers SAL may be formed of or include silicon-germanium (SiGe). The germanium concentration of each of the second semiconductor layers SAL may range from 10 at % to 30 at %.

Mask patterns may be formed on the first and second PMOSFET regions PR1 and PR2 and the first and second NMOSFET regions NR1 and NR2 of the substrate 100, respectively. The mask pattern may be a line- or bar-shaped pattern that is extended in the second direction D2.

A patterning process using the mask patterns as an etch mask may be performed to form the trench TR defining the first and second active patterns AP1 and AP2. The first active pattern AP1 may be formed on each of the first and second PMOSFET regions PR1 and PR2. The second active pattern AP2 may be formed on each of the first and second NMOSFET regions NR1 and NR2. When viewed in a plan view, the first and second active patterns AP1 and AP2 may be line-shaped patterns, which are extended in the second direction D2 to be parallel to each other.

A stacking pattern STP may be formed on each of the first and second active patterns AP1 and AP2. The stacking pattern STP may include the first semiconductor layers ACL and the second semiconductor layers SAL, which are alternately stacked. The stacking pattern STP may be formed along with the first and second active patterns AP1 and AP2, during the patterning process.

The device isolation layer ST may be formed to fill the trench TR. For example, an insulating layer may be formed on the substrate 100 to cover the first and second active patterns AP1 and AP2 and the stacking patterns STP. The device isolation layer ST may be formed by recessing the insulating layer until the stacking patterns STP are exposed.

The device isolation layer ST may be formed of or include at least one of insulating materials (e.g., silicon oxide). The stacking patterns STP may be placed above the device isolation layer ST and may be exposed to the outside of the device isolation layer ST. In other words, the stacking patterns STP may protrude vertically above the device isolation layer ST.

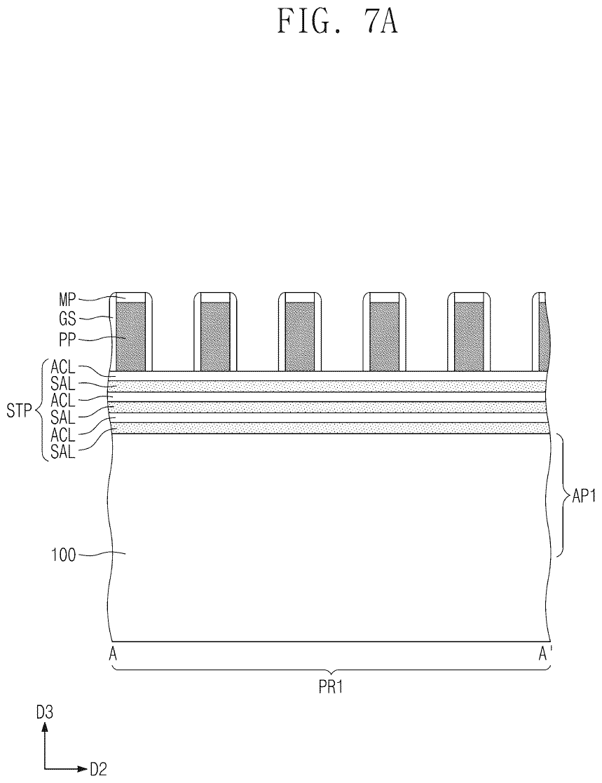

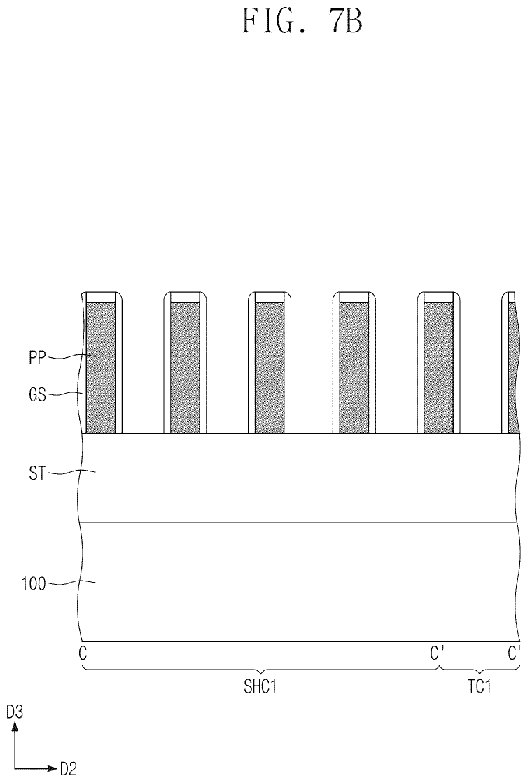

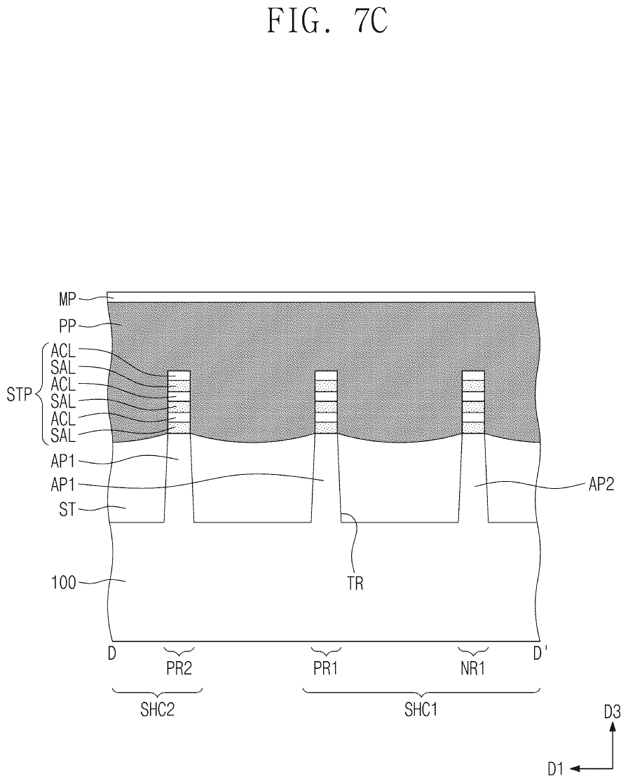

Referring to FIGS. 7A, 7B, and 7C, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

For example, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or include at least one of SiCN, SiCON, or SiN. In an example embodiment, the gate spacer layer may be a multi-layered structure including at least two of SiCN, SiCON, or SiN.

Referring to FIGS. 8A, 8B, and 8C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may also be recessed at both sides of each of the first and second active patterns AP1 and AP2 (e.g., see FIG. 8C).

For example, the first recesses RS1 may be formed by etching the stacking pattern STP on the first active pattern AP1 using the hard mask patterns MP and the gate spacers GS as an etch mask. The first recess RS1 may be formed between a pair of the sacrificial patterns PP. The second recesses RS2 in the stacking pattern STP on the second active pattern AP2 may be formed by the same method as that for the first recesses RS1.

The first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

Referring to FIGS. 9A, 9B, and 9C, the first source/drain patterns SD1 may be formed in the first recesses RS1, respectively. For example, the buffer layer BFL may be formed by a first SEG process using an inner surface of the first recess RS1 as a seed layer. The buffer layer BFL may be grown using the first to third semiconductor patterns SP1, SP2, and SP3 and the substrate 100, which are exposed through the first recess RS1, as a seed layer. As an example, the first SEG process may include a chemical vapor deposition (CVD) process or a molecular beam epitaxy (MBE) process.

The buffer layer BFL may contain a semiconductor material (e.g., SiGe) whose lattice constant is larger than that of a semiconductor material of the substrate 100. The buffer layer BFL may contain a relatively low concentration of germanium (Ge). In another example embodiment, the buffer layer BFL may contain only silicon (Si), without germanium (Ge). A germanium concentration of the buffer layer BFL may range from 0 at % to about 30 at %.

A second SEG process may be performed on the buffer layer BFL to form the main layer MAL. The main layer MAL may be formed to fill the first recess RS1 completely or nearly completely. The main layer MAL may contain a relatively high concentration of germanium. As an example, the germanium concentration of the main layer MAL may range from about 30 at % to about 70 at %.

In an example embodiment, a third SEG process may be performed on the main layer MAL to form a capping layer. The capping layer may be formed of or include silicon (Si). A silicon concentration of the capping layer may range from about 98 at % to 100 at %.

The first source/drain pattern SD1 may be doped in-situ with p-type impurities (e.g., boron, gallium, or indium) during the formation of the buffer and main layers BFL and MAL. In some example embodiments, impurities may be injected into the first source/drain pattern SD1, after the formation of the first source/drain pattern SD1.

The second source/drain patterns SD2 may be formed in the second recesses RS2, respectively. For example, the second source/drain pattern SD2 may be formed by a SEG process, in which an inner surface of the second recess RS2 is used as a seed layer. In an example embodiment, the second source/drain pattern SD2 may be formed of or include the same semiconductor material (e.g., Si) as the substrate 100.

During the formation of the second source/drain pattern SD2, the second source/drain pattern SD2 may be doped in-situ with n-type impurities (e.g., phosphorus, arsenic, or antimony). In some example embodiments, impurities may be injected into the second source/drain pattern SD2, after the formation of the second source/drain pattern SD2.

In an example embodiment, before the formation of the second source/drain pattern SD2, the inner spacer IP may be formed by replacing a portion of the second semiconductor layer SAL, which is exposed by the second recess RS2, with an insulating material. Thus, the inner spacers IP may be respectively formed between the second source/drain pattern SD2 and the second semiconductor layers SAL.

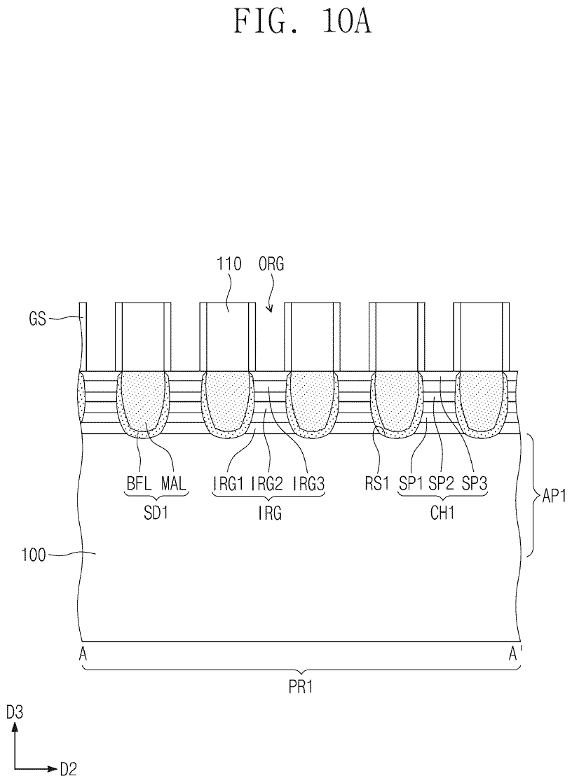

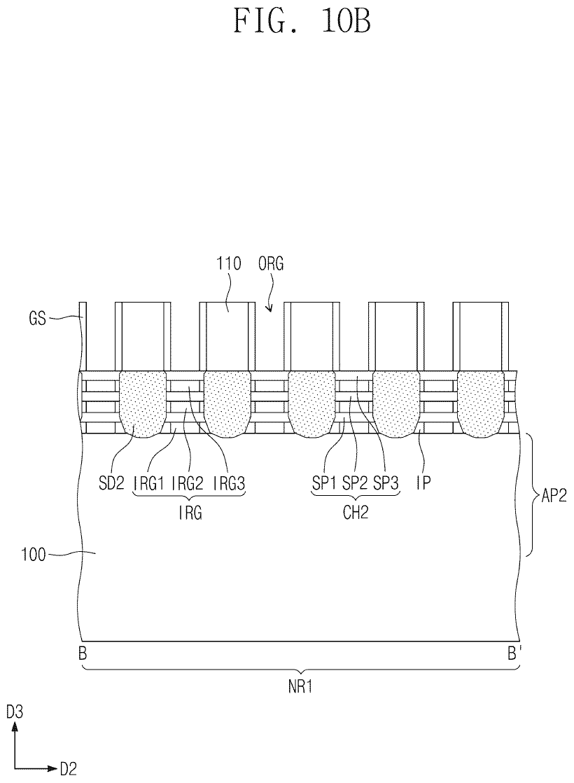

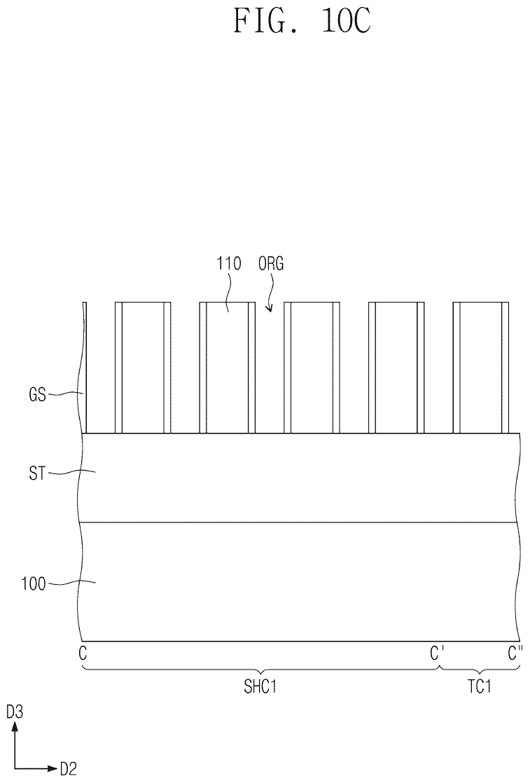

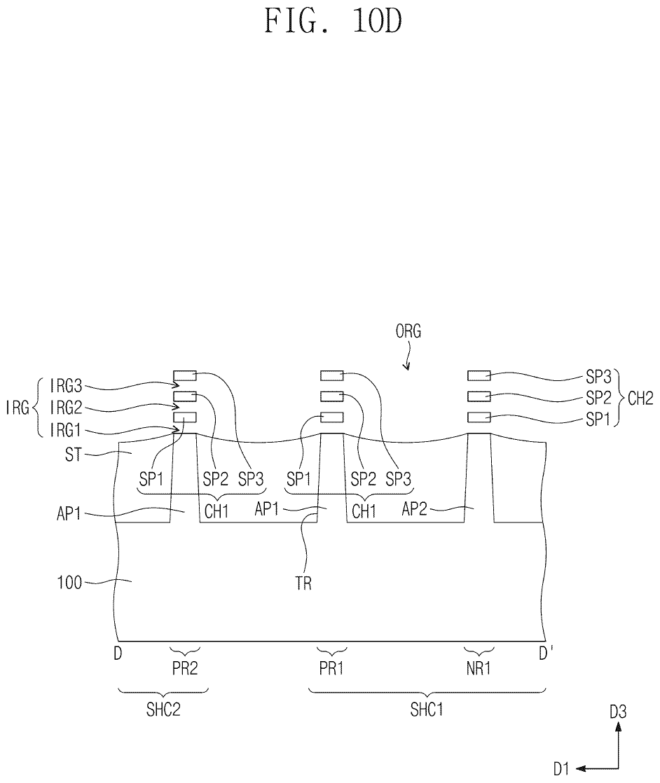

Referring to FIGS. 10A, 10B, 10C, and 10D, the first interlayer insulating layer 110 may be formed to cover the first and second source/drain patterns SD1 and SD2, the hard mask patterns MP, and the gate spacers GS. In an example embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. The hard mask patterns MP may be removed during the planarization process. Thus, the first interlayer insulating layer 110 may be formed to have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP, which is located on a boundary between the first and second single height cells SHC1 and SHC2, may be selectively opened. The opened region of the sacrificial pattern PP may be selectively etched and removed.

In an example embodiment, the exposed sacrificial patterns PP may be selectively removed. Due to the removal of the sacrificial patterns PP, an outer region ORG may be formed to expose the first and second channel patterns CH1 and CH2 (e.g., see FIG. 10D). The removal of the sacrificial patterns PP may include a wet etching process which is performed using an etching solution capable of selectively etching polysilicon.

The second semiconductor layers SAL, which are exposed through the outer region ORG, may be selectively removed to form inner regions IRG (e.g., see FIG. 10D). For example, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which includes a relatively high germanium concentration, at a high etch rate. For example, the etching process may be chosen to have a high etch rate to a silicon germanium layer whose germanium concentration is higher than 10 at %.

During the etching process, the second semiconductor layers SAL may be completely removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration.

Meanwhile, the first source/drain patterns SD1 on the first and second PMOSFET regions PR1 and PR2 may be protected from the etching process by the buffer layer BFL having a relatively low germanium concentration.

Referring back to FIG. 10D, due to the selective removal of the second semiconductor layers SAL, the stacked first to third semiconductor patterns SP1, SP2, and SP3 may be left on each of the first and second active patterns AP1 and AP2. Empty regions, which are formed by removing the second semiconductor layers SAL, may be used as first to third inner regions IRG1, IRG2, and IRG3, respectively.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

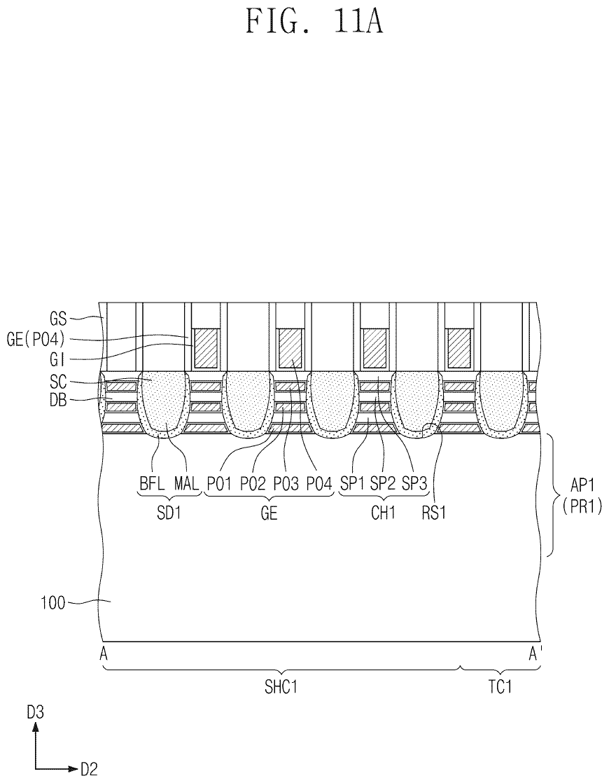

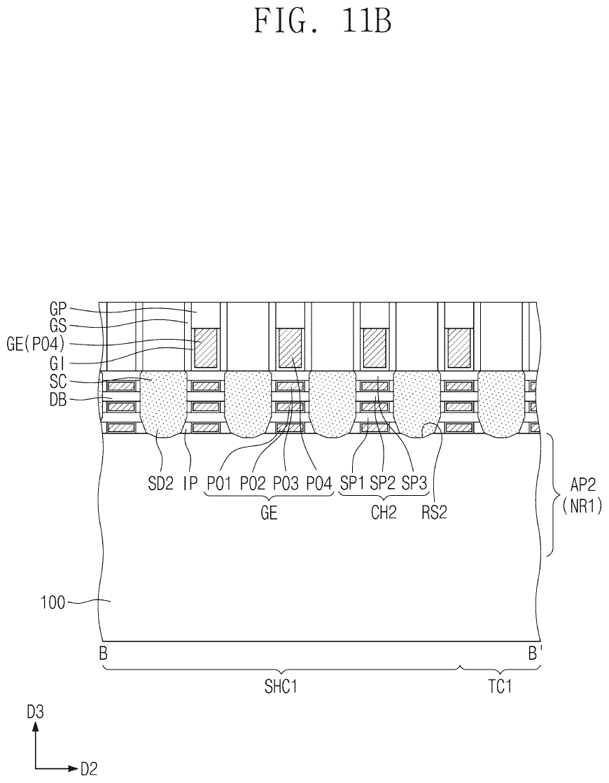

Referring to FIGS. 11A and 11B, the gate insulating layer GI may be conformally formed on the exposed first to third semiconductor patterns SP1, SP2, and SP3. The gate electrode GE may be formed on the gate insulating layer GI. The gate electrode GE may include the first to third inner electrodes PO1, PO2, and PO3, which are formed in the first to third inner regions IRG1, IRG2, and IRG3, and the outer electrode PO4, which is formed in the outer region ORG.

The gate electrode GE may be vertically recessed to have a reduced height. Upper portions of gate cutting patterns CT may be slightly recessed, during the recessing of the gate electrode GE. The gate capping pattern GP may be formed on the recessed gate electrode GE.

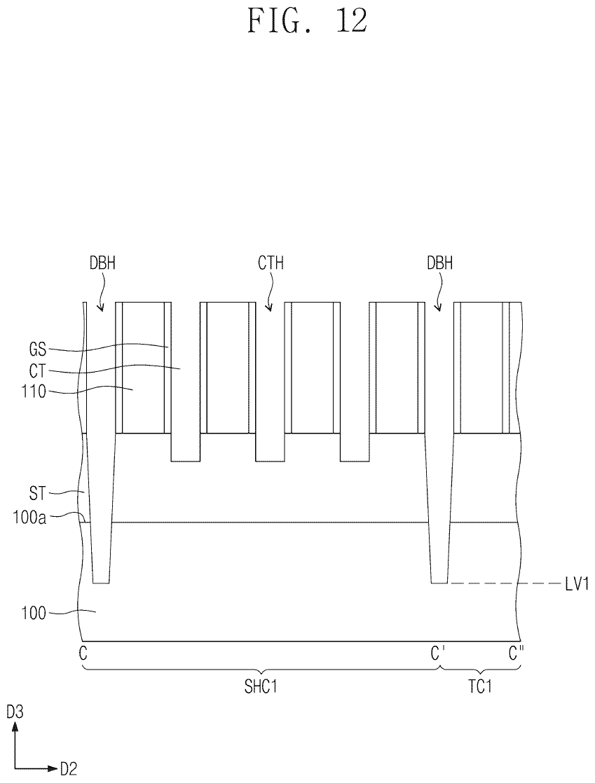

Referring to FIG. 12, cutting holes CTH and division holes DBH may be formed by performing an etching process on a space, which is formed by removing the sacrificial pattern PP. The cutting holes CTH may be formed between the gate spacers GS, which are adjacent to each other. The division holes DBH may be respectively formed at both sides of one cell. The cutting holes CTH may be formed between the division holes DBH, which are formed on one cell. The cutting holes CTH and the division holes DBH may be spaced apart from each other in the second direction D2.

A vertical length of the cutting holes CTH may be smaller than a vertical length of the division holes DBH. As an example, the division holes DBH may be extended to the first level LV1. The first level LV1 may be a height of a bottom surface of the substrate 100 that is etched by a fabrication process to be described below.

The cutting holes CTH may be extended to an upper portion of the device isolation layer ST. The division holes DBH may be provided to penetrate the gate capping pattern GP, the gate electrode GE, and the device isolation layer ST and may be extended into the substrate 100. The division holes DBH may be extended to an upper portion of the substrate 100. As another example, the division holes DBH may be provided to penetrate the substrate 100 and may be coplanar with the bottom surface of the substrate 100.

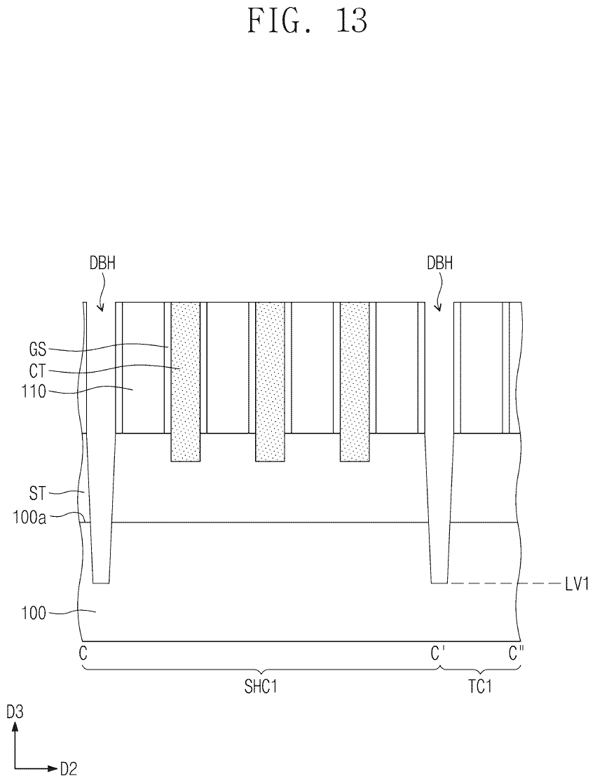

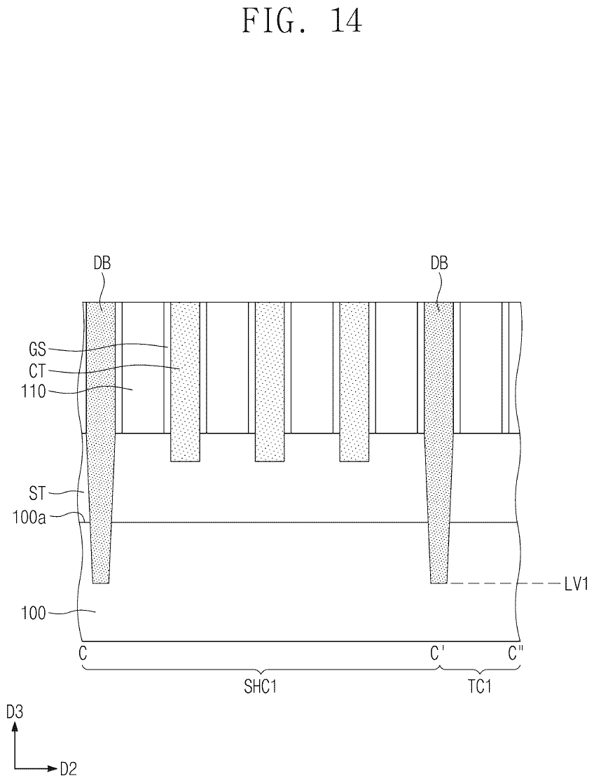

Referring to FIGS. 13 and 14, the gate cutting pattern CT and the division structure DB may be formed by filling the cutting holes CTH and the division holes DBH with an insulating material, respectively. A top surface of the gate cutting pattern CT may be coplanar with a top surface of the division structure DB. The gate cutting pattern CT and the division structure DB may be simultaneously formed by filling the cutting holes CTH and the division holes DBH with an insulating material at the same time.

The division holes DBH may be formed after filling the cutting holes CTH with an insulating material, unlike the structure illustrated in FIGS. 12 and 13. For example, the gate cutting pattern CT and the division structure DB may be formed by different processes from each other.

The division structure DB may be formed on a border between the cells. The division structure DB may penetrate the gate capping pattern GP, the gate electrode GE, and the device isolation layer ST and may be extended into the substrate 100. The lowermost portion of the division structure DB may be located at the first level LV1. A width of the division structure DB in the second direction D2 may decrease as a distance to the bottom surface of the substrate 100 decreases. The division structure DB may be formed of or include an insulating material (e.g., silicon oxide or silicon nitride).

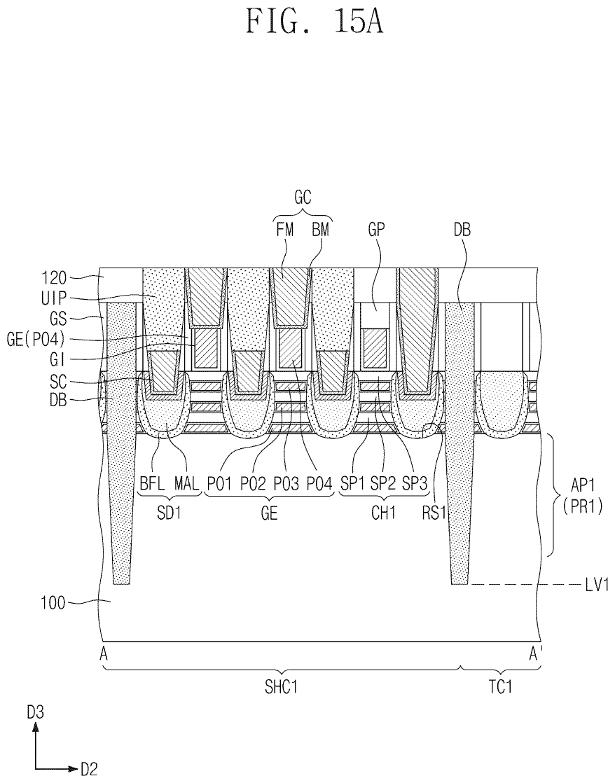

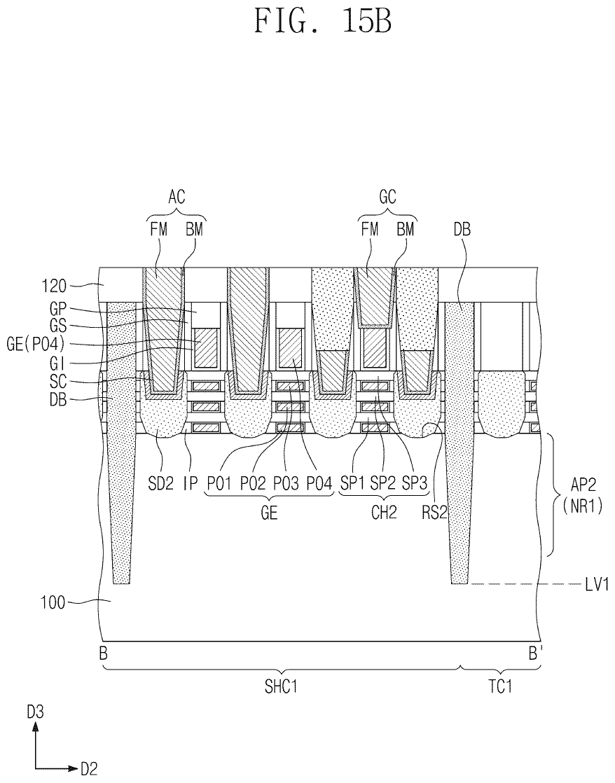

Referring to FIGS. 15A and 15B, the second interlayer insulating layer 120 may be formed on the first interlayer insulating layer 110. The second interlayer insulating layer 120 may cover the top surface of the division structure DB. The second interlayer insulating layer 120 may include a silicon oxide layer. The active contacts AC may be formed to penetrate the second interlayer insulating layer 120 and the first interlayer insulating layer 110 and may be electrically connected to the first and second source/drain patterns SD1 and SD2. The gate contact GC may be formed to penetrate the second interlayer insulating layer 120 and the gate capping pattern GP and may be electrically connected to the gate electrode GE.

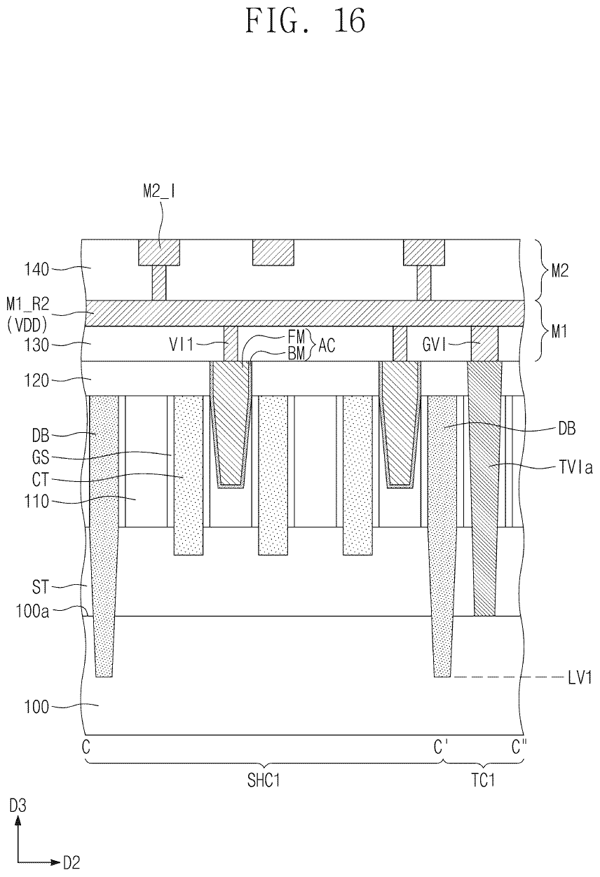

Referring to FIG. 16, a first penetration via portion TVIa may be formed to penetrate the second interlayer insulating layer 120, the first interlayer insulating layer 110, and the device isolation layer ST. A bottom surface of the first penetration via portion TVIa may be located at a level that is substantially equal to or lower than a bottom surface of the device isolation layer ST. Although not shown, the first penetration via portion TVIa may be extended to an upper portion of the substrate 100. A width of the first penetration via portion TVIa in the second direction D2 may decrease as a distance to the bottom surface of the first penetration via portion TVIa decreases.

For example, the formation of the first penetration via portion TVIa may include forming a penetration via hole to penetrate the first and second interlayer insulating layer 110 and 120 and the device isolation layer ST and to expose the substrate 100 and filling the penetration via hole with a metallic material.

The third interlayer insulating layer 130 may be formed on the active contacts AC and the gate contacts GC. The first metal layer M1 may be formed in the third interlayer insulating layer 130. The first metal layer M1 may include the first to third power lines M1_R1, M1_R2, and M1_R3, which are electrically connected to the first penetration via portions TVIa, respectively. The fourth interlayer insulating layer 140 may be formed on the third interlayer insulating layer 130. The second metal layer M2 may be formed in the fourth interlayer insulating layer 140.

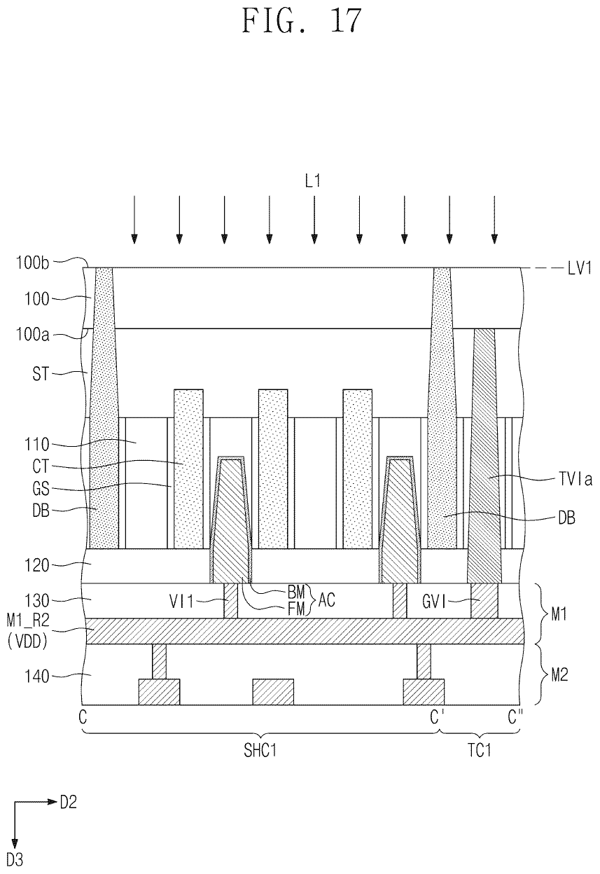

Referring to FIG. 17, the substrate 100 may be inverted such that the bottom surface 100b of the substrate 100 is exposed to the outside, after a BEOL process. A planarization process L1 may be performed on the bottom surface 100b of the substrate 100 to etch the bottom surface 100b of the substrate 100. For example, the planarization process L1 may be performed to reduce a thickness of the substrate 100. In an example embodiment, the planarization process L1 may be performed to expose a bottom surface of the division structure DB. For example, the planarization process L1 may be performed until the bottom surface 100b of the substrate 100 is located at the first level LV1. The planarization process L1 may be performed with different etch rates to the substrate 100 and the division structure DB.

The division structure DB may not be etched, during the planarization process. By contrast, the bottom surface 100b of the substrate 100 may be recessed in a vertical direction D3 or toward the top surface 100a of the substrate 100, during the planarization process. For example, a portion of the bottom surface 100b of the substrate 100 may have a specific curvature. At least a portion of the bottom surface 100b of the substrate 100 may be convex in a vertical direction D3. For example, this structure may be formed when a dishing phenomenon occurs in the planarization process on the substrate 100.

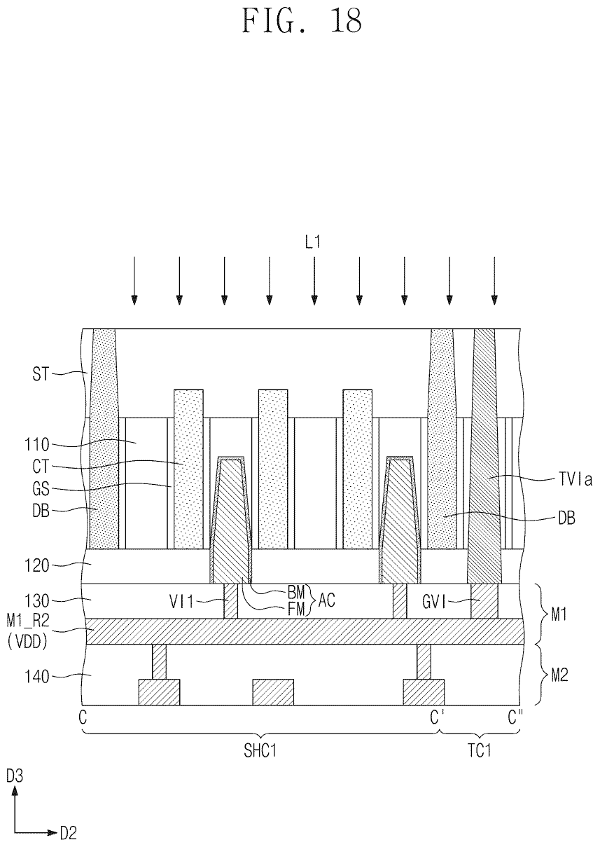

FIG. 18 is a sectional view illustrating a method of fabricating a semiconductor device, according to an example embodiment of the inventive concepts. Referring to FIG. 18, the bottom surface of the division structure DB may be coplanar with the bottom surface of the device isolation layer ST. The planarization process may be performed to fully remove the substrate 100. The division structure DB may be formed of or include a material having an etch selectivity with respect to the device isolation layer ST. The planarization process may be performed to expose the division structure DB and the device isolation layer ST, and in this case, the division structure DB may be used as an etch stopper in the planarization process. In an example embodiment, the cell of FIG. 17 may be adjacent to the cell of FIG. 18, and the tab cell TC1 may be interposed therebetween. The planarization process may be simultaneously performed on two adjacent ones of the cells.

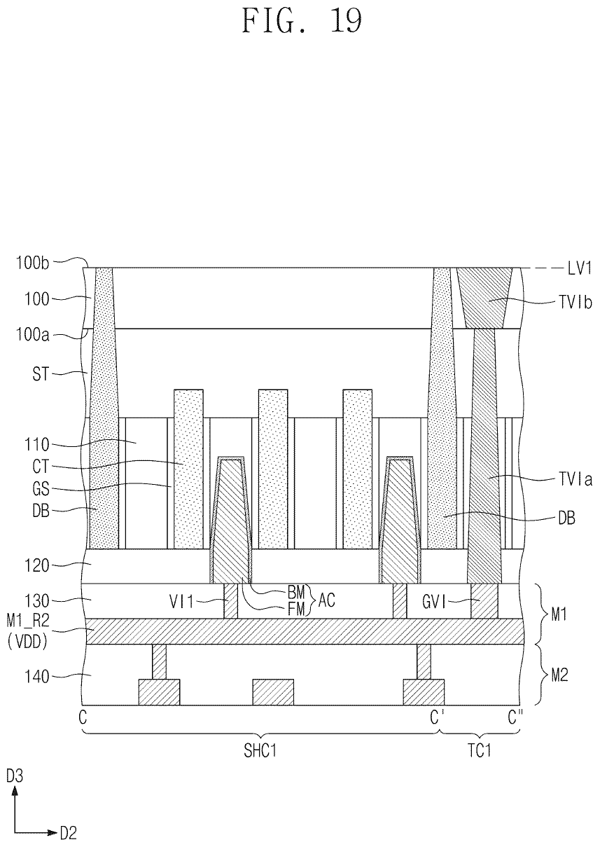

Referring to FIG. 19, a second penetration via portion TVIb may be formed in the substrate 100. For example, the formation of the second penetration via portion TVIb may include performing a patterning process on the bottom surface 100b of the substrate 100 to form a penetration via hole exposing the first penetration via portion TVIa and filling the penetration via hole with a metallic material.

A bottom surface of the second penetration via portion TVIb may be coplanar with the bottom surface 100b of the substrate 100 and the bottom surface of the division structure DB. For example, the bottom surface of the second penetration via portion TVIb may be located at the first level LV1. A width of the second penetration via portion TVIb in the second direction D2 may decrease as a distance to the top surface 100a of the substrate 100 decreases. The first and second penetration via portions TVIa and TVIb may be vertically connected to each other to form the penetration via TVI (e.g., see FIG. 5C). The first and second penetration via portions TVIa and TVIb may be formed of or include the same material.

Thereafter, the power delivery network layer PDN may be formed on the bottom surface 100b of the substrate 100, as shown in FIG. 5C. The power delivery network layer PDN may be formed to apply a source voltage or a drain voltage to the first to third power lines M1_R1, M1_R2, and M1_R3.

In a semiconductor device according to an example embodiment of the inventive concepts, a division structure may penetrate a device isolation layer and may have a bottom surface that is coplanar with a bottom surface of a substrate. The division structure may include a material having an etch selectivity with respect to the substrate. Thus, when the bottom surface of the substrate is etched by a planarization process, the division structure may be used as an etch stopper. By adjusting a height of the division structure, it may be possible to control a final thickness of the substrate after the planarization process. Moreover, by varying the height of the division structure based on the type of the device, it may be possible to alter the thickness of the substrate in each device. This means that by altering the thickness of the substrate, it is possible to improve the electrical and reliability characteristics of the semiconductor device.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
an active pattern on a substrate, defined by a trench, and extending in a first direction;
a device isolation layer filling the trench, the substrate comprising a first surface in contact with a bottom surface of the device isolation layer and a second surface opposite to the first surface;
a gate electrode extending in a second direction and cross the active pattern, the second direction crossing the first direction;
a first division structure spaced apart from the gate electrode in the first direction and extending in the second direction; and
a power delivery network layer on the second surface of the substrate,
wherein the first division structure penetrates the device isolation layer, and
a bottom surface of the first division structure is coplanar with the second surface of the substrate.

2. The semiconductor device of claim 1, wherein the first division structure comprises a material having an etch selectivity with respect to the substrate.

3. The semiconductor device of claim 1, further comprising:
a source/drain pattern on the active pattern;
a first metal layer on the source/drain pattern, the first metal layer comprising a power line; and
a penetration via penetrating the device isolation layer and the substrate and connecting the power line to the power delivery network layer,
wherein a bottom surface of the penetration via is coplanar with the bottom surface of the first division structure.

4. The semiconductor device of claim 1, further comprising:
a first cell and a second cell that are adjacent to each other,
wherein the first division structure electrically separates the first and second cells from each other.

5. The semiconductor device of claim 1, further comprising:
a second division structure spaced apart from the first division structure in the first direction and extending in the second direction,
wherein a bottom surface of the second division structure is coplanar with the bottom surface of the device isolation layer.

6. The semiconductor device of claim 1, wherein the bottom surface of the first division structure is in contact with a lower interconnection line in the power delivery network layer.

7. The semiconductor device of claim 1, wherein a vertical length of a portion of the first division structure in the device isolation layer is larger than a vertical length of a portion of the first division structure in the substrate.

8. The semiconductor device of claim 1, further comprising:
a channel pattern on the active pattern,
wherein the channel pattern comprises a plurality of semiconductor patterns, which are stacked to be spaced apart from each other, and
the gate electrode encloses side surfaces, a top surface, and a bottom surface of each of the semiconductor patterns.

9. The semiconductor device of claim 1, wherein a portion of the second surface is convex in a vertical direction, when viewed in a sectional view and has a curvature.

10. A semiconductor device, comprising:
an active pattern on a substrate, defined by a trench, and extending in a first direction;
a device isolation layer filling the trench;
a source/drain pattern on the active pattern;
a gate electrode extending in a second direction and cross the active pattern, the second direction crossing the first direction;
a first division structure spaced apart from the gate electrode in the first direction and extending in the second direction;
a power delivery network layer on a bottom surface of the substrate;
a first metal layer on the source/drain pattern, the first metal layer comprising a power line; and
a penetration via vertically penetrating the substrate and the device isolation layer and connecting the power line to the power delivery network layer,
wherein the penetration via is at a side of the division structure and is spaced apart from the division structure, and
a bottom surface of the division structure is coplanar with a bottom surface of the penetration via.

11. The semiconductor device of claim 10, wherein the first division structure comprises a material having an etch selectivity with respect to the substrate.

12. The semiconductor device of claim 10, further comprising:
a first cell and a second cell that are adjacent to each other, and
the first division structure electrically separates the first and second cells from each other.

13. The semiconductor device of claim 10, wherein the bottom surface of the division structure is in contact with a lower interconnection line in the power delivery network layer.

14. The semiconductor device of claim 10, wherein
the bottom surface of the first division structure is coplanar with the bottom surface of the substrate, and
a portion of the bottom surface of the substrate is convex in a vertical direction, when viewed in a sectional view, and has a curvature.

15. The semiconductor device of claim 10, wherein
the first division structure penetrates the substrate and the device isolation layer,
the first division structure has a first width in a second direction crossing the first direction, and
the first width decreases as a distance to the bottom surface of the first division structure decreases.

16. A semiconductor device, comprising:
an active pattern on a substrate and extending in a first direction;
a device isolation layer defining the active pattern;
a channel pattern and a source/drain pattern on the active pattern, the channel pattern comprising a plurality of semiconductor patterns stacked to be spaced apart from each other;
a gate electrode on the channel pattern and extending in a second direction crossing the first direction, the gate electrode comprising an inner electrode interposed between adjacent ones of the semiconductor patterns;
a gate insulating layer interposed between the gate electrode and the channel pattern;
an inner spacer between the inner electrode and the source/drain pattern;
a gate spacer on a side surface of the gate electrode;
a gate capping pattern on a top surface of the gate electrode;
a gate cutting pattern penetrating the gate electrode;
an interlayer insulating layer on the gate capping pattern and the gate cutting pattern;
an active contact penetrating the interlayer insulating layer and electrically connected to the source/drain pattern;
a gate contact penetrating the interlayer insulating layer and the gate capping pattern and electrically connected to the gate electrode;
a first metal layer on the interlayer insulating layer, the first metal layer comprising a first upper interconnection line electrically connected to the active contact;
a second metal layer on the first metal layer, the second metal layer comprising a second upper interconnection line electrically connected to the first metal layer;
a power delivery network layer on a bottom surface of the substrate, the power delivery network layer comprising a lower interconnection line;
a penetration via penetrating the device isolation layer and the substrate and vertically connecting the first upper interconnection line of the first metal layer to the lower interconnection line; and
a first division structure spaced apart from the gate electrode in the first direction and extending in the second direction,
wherein the first division structure penetrates the device isolation layer and the substrate,
the bottom surface of the substrate is at a first level, and
the first division structure has a smallest width at the first level, when measured in the first direction.

17. The semiconductor device of claim 16, wherein a lowermost portion of the first division structure is located at the first level.

18. The semiconductor device of claim 16, further comprising
a first cell and a second cell that are adjacent to each other,
wherein the first division structure electrically separates the first and second cells from each other.

19. The semiconductor device of claim 16, wherein a bottom surface of the first division structure is coplanar with a bottom surface of the penetration via.

20. The semiconductor device of claim 16, wherein the first division structure comprises a material having an etch selectivity with respect to the substrate.
